(19) United States
(12) Patent Application Publication
(10) Pub. No.: US 2006/0137741 A1
(43) Pub. Date: Jun. 29, 2006

(54) Photoanode using carbon nanotubes, method of manufacturing the photoanode, and photovoltaic solar cell including the photoanode

(75) Inventors: Young-jun Park, Suwon-si (KR); Sang-cheol Park, Seoul (KR); Won-cheol Jung, Seoul (KR); Jung-gyu Nam, Yongin-si (KR); Ha-jin Kim, Suwon-si (KR)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: Samsung Electronics Co., Ltd., Suwon-si (KR)

(21) Appl. No.: 11/316,865

(22) Filed: Dec. 27, 2005

(30) Foreign Application Priority Data
Dec. 27, 2004 (KR) 10-2004-0113208

(51) Int. Cl. H01L 31/00

(52) U.S. Cl. 136/263

(57) ABSTRACT

Provided are a photoanode including: a conductive substrate; carbon nanotubes and a semiconductor formed on the conductive substrate; and a photosensitizer formed on the carbon nanotubes and the semiconductor, and a solar cell including the photoanode. In the photoanode, the conductive carbon nanotubes can be directly formed on the conductive substrate, thereby promoting electron transfer, unlike in a common photoanode with no carbon nanotubes. In particular, densely formed, branched carbon nanotubes can serve as electron transfer channels between semiconductor particles, thereby enabling an effective application to solar cells, etc.

### CROSS-REFERENCE TO RELATED PATENT APPLICATION

Priority is claimed to Korean Patent Application No. 10-2005-0113208, filed on Dec. 27, 2004, in the Korean Intellectual Property Office, the disclosure of which is incorporated herein in its entirety by reference.

### 1. FIELD OF THE INVENTION

The present invention relates to a solar cell including carbon nanotubes, and more particularly, to a photoanode which can improve energy conversion efficiency using branched carbon nanotubes directly grown on a substrate, and a photovoltaic solar cell including the same.

### 2. DESCRIPTION OF THE RELATED ART

Amorphous silicon solar cells are representative of currently available solar cells. The amorphous silicon solar cells were commercially available long ago due to their high energy conversion efficiency and have been most widely used among solar cells. However, expensive, high-purity silicon is required for operating the silicon solar cells, which restricts commercial application of the silicon solar cells. Thus, various attempts to develop high-efficiency solar cells which are newly structured using new materials, as alternatives to the silicon solar cells, have been made.

A new type of a dye-sensitized solar cell (Gratzel cell) has been developed by M. Gratzel and coworkers (U.S. Pat. No. 4,927,721). The Graetzel cell has an increased surface area by modifying a surface of a common metal oxide semiconductor into a very rough and porous surface, and exhibits cell efficiency comparable to monocrystalline silicon by utilizing light reflected or scattered from the surface. Since then, based on the structure of the Graetzel cell, many attempts to more efficiently enhance the efficiency of dye-sensitized solar cells have been made.

Most studies done hitherto for efficiency enhancement of photosensitizer-sensitized solar cells are directed to increase an area of a surface of a metal oxide semiconductor contacting with light by fine-scale surface-roughening of the metal oxide semiconductor. For example, cell efficiency can be enhanced by adsorbing photosensitizers, as many as possible, onto a rough and porous surface of a semiconductor obtained by sintering a mixture of nanoparticles and a binder. As conventional techniques related thereto, there are for example Korean Patent Laid-Open Publication Nos. 2001-0111379 and 2003-0073420.

The above-illustrated conventional techniques have been focused on increasing electron production by varying a semiconductor formation method, which makes it possible to produce a considerable amount of electrons around a stack of semiconductor nanoparticles. However, electrons injected into semiconductor particles must travel along a complicated route to reach a conductive electrode, thereby increasing resistance. Thus, the electrons injected into the semiconductor particles are partially migrated into an electrolyte, thereby leading to a reduction in energy conversion efficiency.

Therefore, it is desireable to develop a new technique allowing electrons to easily reach a conductive substrate, thereby increasing electron mobility and preventing electron loss, resulting in an enhancement in energy conversion efficiency.

### SUMMARY OF THE INVENTION

The present invention provides a photoanode including carbon nanotubes.

The present invention also provides a method of manufacturing the photoanode.

The present invention also provides a photovoltaic solar cell including the photoanode.

According to an aspect of the present invention, there is provided a photoanode including: a conductive substrate; carbon nanotubes and a semiconductor formed on the conductive substrate; a photosensitizer formed on the carbon nanotubes and the semiconductor.

The conductive substrate may be a conductive material-coated glass or transparent polymer substrate.

The carbon nanotubes may include carbon nanotube branches grown on surfaces thereof.

The semiconductor may be titanium oxide, niobium oxide, nickel oxide, copper oxide, zirconium oxide, hafnium oxide, strontium oxide, zinc oxide, indium oxide, or tin oxide.

The photosensitizer may be RuL₂(SCN)₂, RuL₂(H₂O)₂, RuL₃, RuL₂, OsL₃, or OsL₂.

According to another aspect of the present invention, there is provided a method of manufacturing a photoanode, the method including: forming carbon nanotubes on a conductive substrate; forming a semiconductor on the conductive substrate on which the carbon nanotubes are formed; and adsorbing a photosensitizer on the carbon nanotubes and the semiconductor.

According to still another aspect of the present invention, there is provided a photovoltaic solar cell including: the photoanode; a counter electrode; and an electrolyte between the photoanode and the counter electrode.

### BRIEF DESCRIPTION OF THE DRAWINGS

The above and other features and advantages of the present invention will become more apparent by describing in detail exemplary embodiments thereof with reference to the attached drawings in which:

FIG. 1A is a scanning electron microscopic (SEM) image of carbon nanotubes directly grown on a substrate using plasma chemical vapor deposition (CVD) and FIG. 1B is a SEM image of carbon nanotubes directly grown on a substrate using thermal CVD;

FIG. 2 is a SEM image of branched carbon nanotubes;

FIG. 3 is a transmission electron microscopic (TEM) image of branched carbon nanotubes;

FIG. 4 is a schematic diagram illustrating a process of forming carbon nanotubes;

FIG. 5 is a schematic sectional view of a photovoltaic solar cell according to the present invention; and

FIG. 6 is a schematic diagram illustrating a process of manufacturing a photovoltaic solar cell.

### DETAILED DESCRIPTION OF THE INVENTION

The present invention will now be described more fully with reference to the accompanying drawings.

A photoanode according to exemplary embodiments of the present invention includes carbon nanotubes, a semiconductor, and a photosensitizer. In a common photoanode including only a semiconductor and a photosensitizer, a considerable amount of electrons injected into the semiconductor are migrated to an electrolyte and wasted due to a resistance caused upon electron transfer to a conductive substrate. On the contrary, in the photoanode of exemplary embodiments of the present invention, due to the carbon nanotubes with high electroconductivity, electrons injected into the semiconductor can be rapidly migrated to a conductive substrate without electron loss, thereby improving energy conversion efficiency.

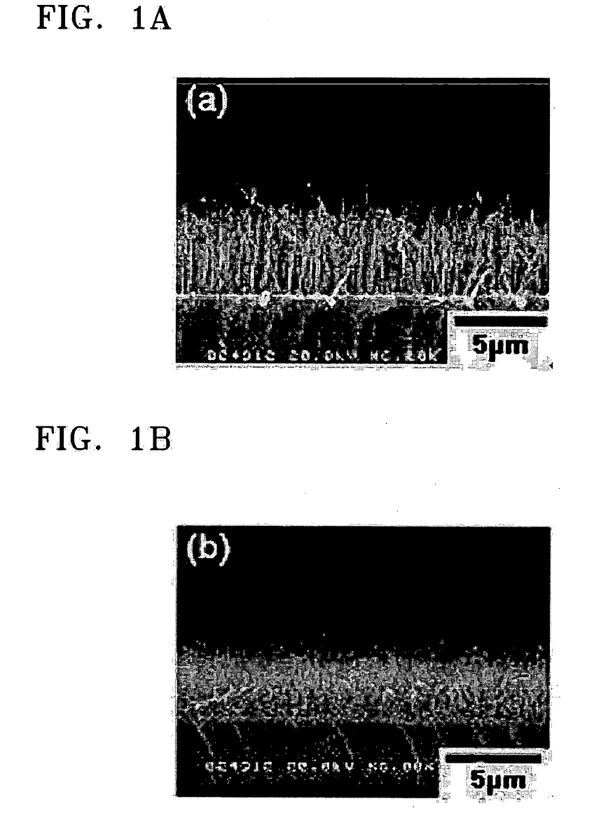

In the photoanode of exemplary embodiments of the present invention, carbon nanotubes are formed on a conductive substrate, metal oxide semiconductor particles are stacked on the carbon nanotubes, and a photosensitizer is adsorbed onto the carbon nanotubes and the metal oxide semiconductor particles. The carbon nanotubes may be directly grown on the conductive substrate. FIG. 1A is a scanning electron microscopic (SEM) image of carbon nanotubes directly grown on a substrate using plasma chemical vapor deposition (CVD) and FIG. 1B is a SEM image of carbon nanotubes directly grown on a substrate using thermal CVD. Referring to FIGS. 1A and 1B, the carbon nanotubes grown by plasma CVD are arranged vertically on the substrate, whereas the carbon nanotubes grown by thermal CVD are arranged randomly on the substrate. The density, diameter, length, and thickness of the carbon nanotubes formed on the substrate can be controlled by changing the process conditions for forming the carbon nanotubes according to the characteristics of a photoanode. Also, the carbon nanotubes can be in various shapes such as straight type, bent type, or twisted type for example.

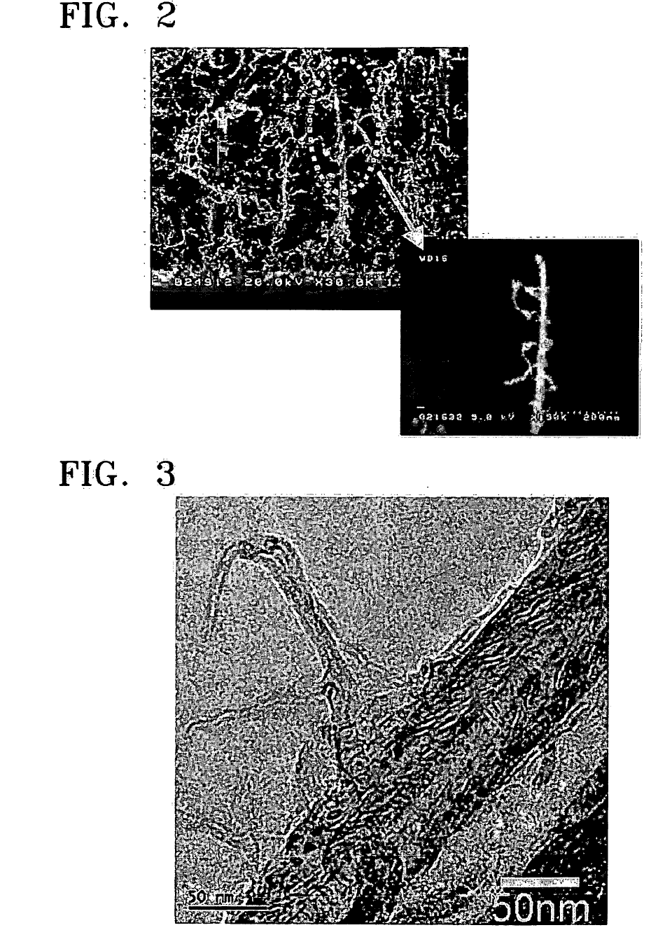

The carbon nanotubes may be branched carbon nanotubes in which side branches are grown on surfaces of carbon nanotube templates. FIG. 2 is a SEM image showing branched carbon nanotubes. The branched carbon nanotubes can be densely dispersed between metal oxide semiconductor nanoparticles, and thus, a distance between electrons injected into the semiconductor nanoparticles and the carbon nanotubes is significantly reduced, thereby ensuring a rapid electron transfer.

The branched carbon nanotubes can also be called “fractal-like carbon nanotubes”. The fractal structure is a complex and irregular structure created by iteration of simple structure. For example, the fractal structure of lightning is a huge lightning structure created by repeating the formation of stems and side branches from a lightning trunk. That is, the fractal structure of carbon nanotubes refers to a structure created by repeating the formation of carbon nanotube stems and branches from straight carbon nanotube templates.

The carbon nanotubes may be aligned vertically on the conductive substrate. At this time, the carbon nanotubes may include side branches grown on surfaces thereof. The vertical alignment of the carbon nanotube templates with respect to the conductive substrate enables to produce a maximally dense carbon nanotube structure. Furthermore, the growth of the side branches from the carbon nanotube templates can increase the total volume of the carbon nanotube structure. The orientation of the side branches grown from the carbon nanotube templates is not limited. The side branches can be randomly oriented.

The carbon nanotubes may be metallic conductors. Generally, carbon nanotubes exhibit various quantum effects specifically observed in lower-dimensional structures due to their quasi-one-dimensional structures, and at the same time, are excellent in mechanical stability and elasticity, and chemical stability. Carbon nanotubes show semiconducting or conducting property according to their structures. Metallic carbon nanotubes can serve as interconnections that do not chemically react with an electrolyte and can promote electron transfer to a conductive substrate with no resistance due to higher electroconductivity than copper. In semiconducting carbon nanotubes, electron transfer to a conductive substrate may be retarded due to low conductivity.

The carbon nanotubes may be grown from metal catalytic particles pre-formed on the conductive substrate. As the carbon nanotubes grow, the metal catalytic particles are dispersed in inner and outer walls of the carbon nanotubes. Preferably, metal catalytic nanoparticles may be uniformly dispersed in the inner and outer walls of the carbon nanotubes with degree of dispersion of 0.3 to 5 mg/□. If the degree of dispersion of the metal catalytic particles is less than 0.3 mg/□, catalytic reactivity may be insufficient. On the other hand, if it exceeds 5 mg/□, the catalyst particles may be agglomerated, which makes it difficult to grow the carbon nanotubes using this exemplary technique. FIG. 3 is a transmission electron microscopic (TEM) image of branched carbon nanotubes. Referring to FIG. 3, metal catalyst particles (marked with black) are dispersed in carbon nanotubes, and the carbon nanotubes form a fractal structure by iterative growth from the catalyst particles.

The conductive substrate having thereon the carbon nanotubes and the semiconductor may be a conductive material-coated glass or transparent polymer substrate, but the present invention is not limited thereto. The conductive material is not limited provided that it has conductivity and transparency. However, a tin-based oxide is suitable due to good heat resistance, in addition to conductivity and transparency. In view of cost effectiveness, indium tin oxide (ITO) is preferable.

The semiconductor formed on the conductive substrate may be microparticles or nanoparticles of a semiconductor such as a compound semiconductor or a perovskite-type compound. The semiconductor may be an n-type semiconductor in which electrons in a conduction band act as carriers under a photo-excitation condition to generate anode current. The semiconductor may be titanium oxide, niobium oxide, nickel oxide, copper oxide, zirconium oxide, hafnium oxide, strontium oxide, zinc oxide, indium oxide, tin oxide, etc, more preferably, TiO₂, SnO₂, ZnO, WO₃, Nb₂O₅, or TiSrO₃, and particularly preferably, anatase-type TiO₂.

The photosensitizer adsorbed onto the carbon nanotubes and the semiconductor may be a metal complex such as RuL₂(SCN)₂, RuL₂(H₂O)₂, RuL₃, RuL₂, OsL₃, and OsL₂. Here, L is at least one ligand selected from the group consisting of 2,2′-bipyridyl-4,4′-dicarboxylate and 2,2′-bipyridine. However, the photosensitizer is not particularly limited provided that it can show charge separation and photosensitizing action. Examples of the photosensitizer include xanthene dyes such as Rhodamine B, Rose Bengal, Eosine, or erythrosine; cyanine dyes such as quinocyanine or cryptocyanine; basic dyes such as phenosafranine, Capri Blue, thiosine, or Methylene Blue; porphyrin-type compounds such as chlorophyll, zinc porphyrin, or magnesium porphyrin; azo dyes; phthalocyanine compounds; anthraquinone dyes; and polycyclic quinone dyes.

The present invention also provides a method of manufacturing a photoanode, an exemplary method including: forming carbon nanotubes on a conductive substrate; forming a semiconductor on the conductive electrode having thereon the carbon nanotubes; and adsorbing a photosensitizer onto the carbon nanotubes and the semiconductor.

The forming of the carbon nanotubes on the conductive substrate may be performed by CVD for carbon nanotube synthesis or by forming a carbon nanotube paste obtained by mixing the carbon nanotubes with an organic material.

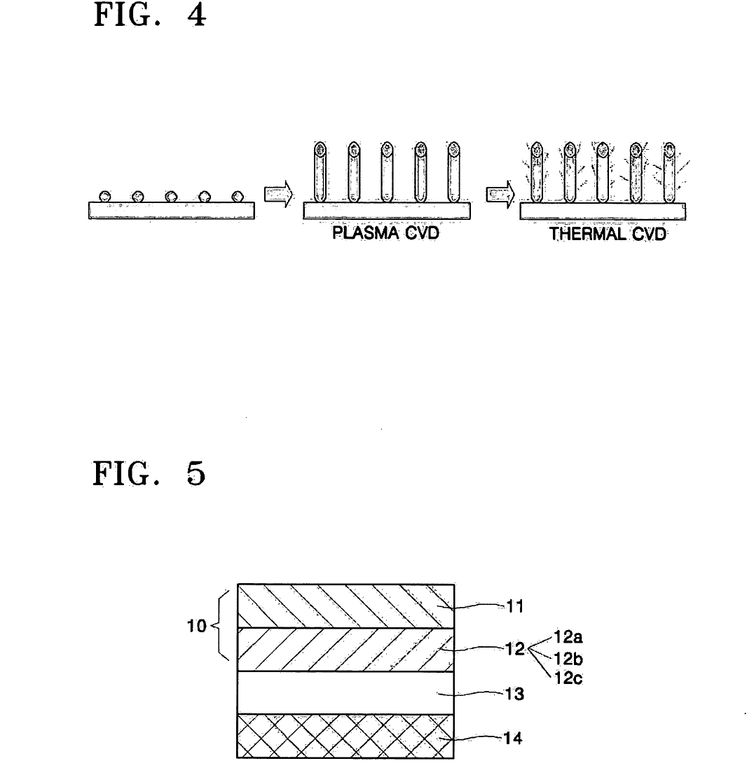

The formation of carbon nanotubes using CVD may include uniformly dispersing a metal catalyst on the conductive substrate, growing carbon nanotubes using plasma CVD, and then growing carbon nanotubes using thermal CVD. This process is schematically illustrated in FIG. 4.

In addition to the above-illustrated process, plasma CVD may be preceded by thermal CVD. Furthermore, plasma CVD and thermal CVD may be used alone or may also be appropriately alternately repeated.

In detail, first, the metal catalyst is pre-formed on the conductive substrate to assist initial formation of the carbon nanotubes. The metal catalyst pre-formed on the conductive substrate may be a metal-containing organometallic compound or oxide, or any metal selected from Fe, Co, Ni, Cr, Invar [Fe 52%, Ni 42%, Co 6%], Mo, Pd, and Y. The pre-forming of the metal catalyst on the conductive substrate may be performed using electrophoresis, thermal spray, sputtering, electroplating, or CVD. For example, cobalt is typically sputtered on a substrate.

Next, a carbon source gas for synthesis of the carbon nanotubes is supplied. The carbon source gas may be ammonia, acetylene, ethylene, methane, carbon monoxide, xylene, etc.

The metal catalyst on the conductive substrate is heated while increasing a chamber temperature. At this time, to lower the total energy, the metal catalyst is formed into three-dimensional particles or hemispheres by surface tension. Such particles or hemispheres play an important role in growth of carbon nanotubes. When the carbon source gas is converted to a plasma state, carbon nanotubes start to grow from the metal catalyst. The carbon nanotubes are grown straight and aligned vertically with respect to the bias direction of electric field. That is, the carbon nanotubes grown by plasma CVD are aligned vertically on the conductive substrate. At this time, the metal catalyst is dispersed in the inner and outer walls of the carbon nanotubes since it moves along the growing carbon nanotubes.

In this state, when the carbon nanotubes are subjected to thermal CVD, carbon nanotube branches are grown from the metal catalyst dispersed in the carbon nanotubes, resulting in branched carbon nanotubes wherein the carbon nanotube branches are grown on surfaces of the carbon nanotube templates.

The forming of the carbon nanotubes on the conductive substrate is not limited to the above-illustrated example. Other technologies known in the art for forming nanotubes can also be used.

In the above-illustrated forming of the carbon nanotubes on the conductive substrate, the thickness of a metal catalyst layer, the internal temperature of a chamber, a temperature elevation rate, plasma frequency, the growth rate of the carbon nanotubes, etc. can be adjusted to control the density, diameter, length, or thickness of the carbon nanotubes. Therefore, carbon nanotubes tailored to the requirements of a photoanode and a photovoltaic solar cell using the same can be formed.

The forming of the semiconductor on the conductive electrode having thereon the carbon nanotubes may be performed using electrophoresis, screen printing, doctor blade, sol-gel, dip-coating, etc. It is preferable to use a technique capable for densely forming the semiconductor, i.e., metal oxide semiconductor nanoparticles on the conductive substrate. When the semiconductor is formed on the conductive substrate, the resultant structure is sintered so that the carbon nanotubes and the semiconductor are contacted and connected to each other.

Finally, when a photosensitizer solution is contacted to the conductive substrate on which the carbon nanotubes and the semiconductor are formed, the photosensitizer is adsorbed onto the carbon nanotubes and the semiconductor. This completes a photoanode.

A photovoltaic solar cell using the above-illustrated photoanode is illustrated in FIG. 5. Referring to FIG. 5, a photovoltaic solar cell includes a photoanode 10, a counter electrode 14, and an electrolyte 13 between the photoanode 10 and the counter electrode 14.

The photoanode 10 includes a conductive substrate 11, and a photovoltaic layer 12 comprised of carbon nanotubes 12a, a semiconductor 12b, and a photosensitizer 12c. The carbon nanotubes 12a, the semiconductor 12b, and the photosensitizer 12c are as described above.

The electrolyte 13 is in the form of a liquid electrolyte. The electrolyte 13 includes the photoanode 10 or permeates into the photoanode 10. The electrolyte 13 may be iodide, bromide, or hydroquinone, but is not limited provided that it can show a hole conduction function.

The counter electrode 14 is not limited provided that it is made of a conductive material. The counter electrode 14 may also be made of an insulating material provided that a conductive layer is formed on a side of the counter electrode 14 facing with the photoanode 10. The conductive layer is generally a transparent nonconductor coated with a conductive material. The counter electrode 14 may be made of an electrochemically stable material, e.g., platinum, gold, or carbon. Furthermore, the side of the counter electrode 14 facing with the photoanode 10 may have a large surface-area microstructure to increase the efficiency of redox catalytic reaction. For example, platinum black or porous carbon may be applied to the side of the counter electrode facing with the photoanode 10. The platinum black may be formed by anodizing platinum or chloroplatinic acid treatment, and the porous carbon may be formed by sintering carbon microparticles or an organic polymer.

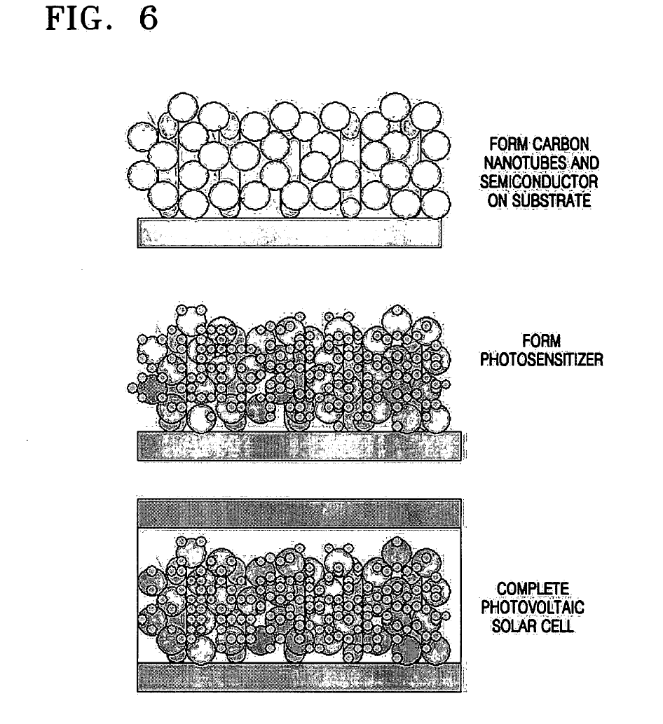

A method of manufacturing a photovoltaic solar cell with the above-illustrated structure is not particularly limited. Any method commonly known in the art can be used. A process of manufacturing a photovoltaic solar cell according to an exemplary embodiment of the present invention is schematically illustrated in FIG. 6. As illustrated, carbon nanotubes and a semiconductor are formed on a conductive substrate. Thereafter, a photosensitizer is interspersed in the carbon nanotubes and semiconductor. The photovoltaic solar cell is completed with the addition of a counterelectrode, though the order of these steps be varies, as explained below.

Hereinafter, the present invention will be described more specifically with reference to the following examples. The following examples are for illustrative purposes and are not intended to limit the scope of the invention.

Manufacturing of Photoanodes

### EXAMPLE 1

First, an Invar layer, which was a metal catalyst layer, was formed to a thickness of 1 to 10 nm using sputtering on a transparent and conductive glass substrate coated with ITO and having a transmittance of 80%.

Next, carbon nanotubes were grown vertically on the conductive substrate using plasma CVD in a hot filament plasma-enhanced CVD (HFPECVD) system (Mat Sci Tech model CNT-2000). Ammonia and acetylene were used as carbon source gases. During the growth of the carbon nanotubes, a substrate temperature was maintained at 5000, and a chamber pressure was maintained at 3.2 Torr. The gas flow rates of ammonia and acetylene were kept 120 sccm (standard cubic centimeter per minute) and 30 sccm, respectively, and a total growth time was 20 minutes at a bias voltage of 580V and a filament current of 11.1 A.

Next, carbon nanotubes were grown using thermal CVD to obtain branched carbon nanotubes. GNCVD300 was used as a thermal CVD system, and hydrogen and carbon monoxide were used as carbon source gases. During the growth of the carbon nanotubes, a substrate temperature was maintained at 550□, and a chamber pressure was maintained at 50 Torr. The gas flow rates of hydrogen and carbon monoxide were kept 1.0 sccm and 0.5 sccm, respectively, and a total growth time was 20 minutes.

Next, a titanium dioxide (TiO₂) colloid solution was prepared by hydrothermal synthesis using titanium isopropoxide and acetic acid. A solvent was evaporated from the colloid solution until the content of titanium dioxide in the colloid solution reached 10 volume % to thereby obtain a concentrated titanium dioxide colloid solution containing titanium dioxide nanoparticles. Then, hydroxypropylcellulose (Mw: 80000) was added to the concentrated titanium dioxide colloid solution and stirred for 24 hours to make a titanium dioxide coating slurry. Then, the titanium dioxide coating slurry was coated on the ITO-coated glass substrate having thereon the carbon nanotubes using a doctor blade method and heated at about 450□ for one hour to remove an organic polymer and to guarantee a contact and filling between the titanium dioxide nanoparticles and the carbon nanotubes. As a result, a film composed of the carbon nanotubes and the titanium dioxide nanoparticles was formed to a thickness of 10□ on the transparent and conductive glass substrate.

Next, the glass substrate thereon having the carbon nanotubes and the titanium dioxide nanoparticles was dipped in a ruthenium dithiocyanate 2,2′-bipyridyl-4,4′-dicarboxylate solution for 12 hours and dried to form a photosensitizer.

Next, the resultant glass substrate was cleaned with deionized water to thereby complete a photoanode.

### EXAMPLE 2

A photoanode was manufactured in the same manner as in Example 1 except that the forming of carbon nanotubes using thermal CVD was omitted.

### COMPARATIVE EXAMPLE

A photoanode was manufactured in the same manner as in Example 1 except that the forming of carbon nanotubes on a conductive substrate was omitted so that only a semiconductor and a photosensitizer were present on a glass substrate.

Manufacturing of Photovoltaic Solar Cells

Photovoltaic solar cells were manufactured using the photoanodes manufactured in Examples 1-2 and Comparative Example.

First, a counter electrode to be coupled to each photoanode manufactured in Examples 1-2 and Comparative Example was manufactured. That is, a platinum layer was coated on a transparent and conductive glass substrate coated with ITO.

Next, the counter electrode and the photoanode were assembled. The assembling was performed so that the platinum layer of the counter electrode faced with the semiconductor of the photoanode. At this time, the counter electrode and the photoanode were closely adhered to each other on about 100-1400 heating plate by means of a polymer layer made of SURLYN (manufactured by DuPont) having a thickness of about 40 □ as an intermediate layer between the two electrodes under about 1-3 atm. The SURLYN polymer was adhered to the surfaces of the two electrodes by heat and pressure.

Next, a space defined by the two electrodes was filled with an electrolyte solution through micropores previously formed on the surface of the counter electrode.

The electrolyte solution was an I₃⁻/I⁻ electrolyte solution obtained by dissolving 0.6M 1,2-dimethyl-3-octyl-imidazolium iodide, 0.2M Lil, 0.04M 12, and 0.2M 4-tert-butylpyridine (TBP) in acetonitrile.

Measurement of Energy Conversion Efficiency

The current-voltage characteristics of the solar cells manufactured in the above were evaluated under AM 1.5 conditions (100 mW/□). A 1000 W sulfur lamp was used as a light source, and light intensity was adjusted to the AM 1.5 conditions using a silicon solar cell equipped with a KG-5 filter (manufactured by Schott Optical Company). The energy conversion efficiency based on photocurrent-photovoltage measurements was calculated.

According to the experimental results, the energy conversion efficiency was revealed as follows: Example 1>Example 2>Comparative Example. The solar cells manufactured using the photoanodes in which the carbon nanotubes were grown on the conductive substrate according to Examples 1-2 exhibited relatively good energy conversion efficiency compared to the solar cell manufactured using the photoanode of Comparative Example. The solar cells manufactured using the photoanode in which the branched carbon nanotubes were grown using both plasma CVD and thermal CVD according to Example 1 exhibited the most excellent energy conversion efficiency. The enhancement in energy conversion efficiency in the solar cells manufactured using the photoanodes of Examples 1-2 is attributed to fast electron transfer by the carbon nanotubes. In particular, the excellent energy conversion efficiency in the solar cell manufactured using the photoanode of Example 1 is attributed to faster electron transfer by the densely formed, branched carbon nanotubes.

In an exemplary photoanode according to the present invention, conductive carbon nanotubes are directly formed on a conductive substrate, thereby promoting electron transfer, unlike in a conventional photoanode with no carbon nanotubes. In particular, densely formed, branched carbon nanotubes can serve as electron transfer channels between semiconductor particles, thereby enabling an effective application to solar cells, etc.

The present invention has been described by way of exemplary embodiments, to which it is not limited. Variations and modifications will occur to those skilled in the art without departing from the scope of the present invention as recited in the claims appended hereto.

What is claimed is:

1. A photoanode comprising:
a conductive substrate;
carbon nanotubes and a semiconductor formed on the conductive substrate;
a photosensitizer formed on the carbon nanotubes and the semiconductor.

2. The photoanode of claim 1, wherein the carbon nanotubes are directly formed on the conductive substrate.

3. The photoanode of claim 1, wherein the carbon nanotubes comprise carbon nanotube branches grown on surfaces thereof.

4. The photoanode of claim 1, wherein the carbon nanotubes have a fractal structure.

5. The photoanode of claim 1, wherein the carbon nanotubes are aligned vertically on the conductive substrate.

6. The photoanode of claim 5, wherein the carbon nanotubes comprise carbon nanotube branches grown on surfaces thereof.

7. The photoanode of claim 1, wherein the carbon nanotubes are conductors.

8. The photoanode of claim 1, wherein the conductive substrate is a conductive material-coated glass or transparent polymer substrate.

9. The photoanode of claim 1, wherein the semiconductor is at least one metal oxide semiconductor selected from the group consisting of titanium oxide, niobium oxide, nickel oxide, copper oxide, zirconium oxide, hafnium oxide, strontium oxide, zinc oxide, indium oxide, and tin oxide.

10. The photoanode of claim 1, wherein the photosensitizer is at least one metal complex selected from the group consisting of RuL₂(SCN)₂, RuL₂(H₂O)₂, RuL₃, RuL₂, OsL₃, and OsL₂.

11. A method of manufacturing a photoanode, the method comprising:
forming carbon nanotubes on a conductive substrate;
forming a semiconductor on the conductive substrate on which the carbon nanotubes are formed; and
adsorbing a photosensitizer on the carbon nanotubes and the semiconductor.

12. The method of claim 11, wherein the forming of the carbon nanotubes on the conductive substrate is performed by chemical vapor deposition (CVD) for carbon nanotube synthesis or by forming a carbon nanotube paste obtained by mixing the carbon nanotubes with an organic material.

13. The method of claim 12, wherein the forming of the carbon nanotubes on the conductive substrate using CVD comprises:
uniformly dispersing a metal catalyst on the conductive substrate;
growing carbon nanotubes using plasma CVD; and
growing carbon nanotubes using thermal CVD.

14. The method of claim 13, wherein the dispersing of the metal catalyst on the conductive substrate is performed using at least one selected from the group consisting of electrophoresis, thermal spray, sputtering, electroplating, and CVD.

15. The method of claim 13, wherein the growing of the carbon nanotubes using plasma CVD and the growing of the carbon nanotubes using thermal CVD are performed using at least one carbon source gas selected from the group consisting of ammonia, acetylene, ethylene, methane, carbon monoxide, and xylene.

16. The method of claim 13, wherein in the growing of the carbon nanotubes using plasma CVD, the carbon nanotubes are aligned vertically on the conductive substrate.

17. The method of claim 13, wherein in the growing of the carbon nanotubes using thermal CVD, the carbon nanotubes are grown as side branches from surfaces of the carbon nanotubes grown using plasma CVD.

18. The method of claim 13, wherein the metal catalyst dispersed on the conductive substrate is at least one selected from Fe, Co, Ni, Cr, Invar, Mo, Pd, and Y.

19. The method of claim 11, wherein the forming of the semiconductor on the conductive substrate on which the carbon nanotubes are formed is performed using at least one selected from the group consisting of electrophoresis, screen printing, doctor blade, sol-gel, and dip-coating.

20. A photovoltaic solar cell comprising:
the photoanode of claim 1;
a counter electrode; and
an electrolyte between the photoanode and the counter electrode.
